(19) United States
(12) Patent Application Publication
(10) Pub. No.: US 2022/0230938 A1
(43) Pub. Date: Jul. 21, 2022

(54) POWER MODULE WITH VASCULAR JET IMPINGEMENT COOLING SYSTEM

(71) Applicant: GM GLOBAL TECHNOLOGY OPERATIONS LLC, Detroit, MI (US)

(72) Inventors: Anthony M. Coppola, Rochester Hills, MI (US); Alireza Fatemi, Canton, MI (US); Ronald O. Grover, JR., Northville, MI (US); Ming Liu, Troy, MI (US); Chih-hung Yen, Bloomfield Hills, MI (US)

(73) Assignee: GM GLOBAL TECHNOLOGY OPERATIONS LLC, Detroit, MI (US)

(21) Appl. No.: 17/152,084

(22) Filed: Jan. 19, 2021

(51) Int. Cl. H01L 23/473; H01L 21/48

(52) U.S. Cl. CPC H01L 23/4735; H01L 21/4882

(57) ABSTRACT

A vascular jet cooling system for use with a planar power module and a coolant supply includes a manifold housing and one or more jet impingement plates. The manifold housing is constructed of a dielectric polymer molding material, and defines a coolant inlet port configured to fluidly connect to the coolant supply, an internal cavity in fluid communication with the coolant inlet port and containing the power module, and a coolant outlet port in fluid communication with the internal cavity. The jet impingement plate(s) is arranged in the internal cavity. Openings of the plates direct coolant passing through the coolant inlet port onto a respective major surface of the power module. A power module assembly includes a planar power module and the vascular jet cooling system. A method of constructing the power module assembly uses sacrificial materials and overmolding of the jet impingement plates.

The present disclosure relates to packaging for a two-sided power semiconductor electronic component, referred to hereinafter as a power module for simplicity. More particularly, the present disclosure related to packaging systems and methodologies for conducting a suitable heat transfer fluid/coolant to one or more major surfaces of such a power module for the purpose of thermal regulation.

As appreciated in the art, power modules containing one or more semiconductor switching dies are used in a wide variety of high-voltage electrical systems. For example, a power inverter module is employed within a dual direct current (DC) and alternating current (AC) electrical system. Representative high-voltage electrical systems include electrified powertrains and stationery powerplants in which a DC output voltage from a high-voltage DC battery pack is used to energize one or more phase windings of an electric motor. Power modules are likewise used in DC-DC voltage converters for the purpose of providing an application-suitable DC output voltage.

Within a typical power module resides a set of semiconductor switching dies disposed within a multi-layered substrate, with the switching dies housing one or more insulated-gate bipolar transistors (IGBTs), metal-oxide silicon field effect transistors (MOSFETs), power diodes, thyristors, or other application-suitable semiconductor switches. Collectively, the switches of the power module are used to perform a high-speed/high-power switching function of the type noted generally above when converting AC power to DC power, or vice versa.

The substrate includes electrically conductive layers that function as electrical connections to the various switching dies. Each substrate is typically constructed of a thermally conductive material to facilitate heat transfer away from the sensitive semiconductor switching components. The transferred heat is then dissipated from external surfaces of the power module. Two-sided cooling may be facilitated using a complimentary two-sided cooling system, for instance by clamping the power module between a pair of opposing cooling jackets and employing thermal interface material at interfacing surfaces between the cooling jacket and power module. However, such an approach may be less than optimal in terms of thermal resistance, weight, and packaging size.

### SUMMARY

A vascular jet cooling system is disclosed herein for use with a planar power module. The present solution employs sacrificial molding and polymer encapsulation of a planar power module to facilitate fabrication of a self-contained manifold housing. Within the manifold housing, jet impingement plates serve as nozzle-based or slot-based coolant jets by directing coolant onto an exposed major surface of the planar power module for the purpose of regulating the temperature thereof.

As appreciated in the art, a power module is commonly used as a core component of a power inverter, a direct current-to-direct current (DC-DC) converter, and other types of integrated power conversion systems. Heat is generated during the ongoing high-speed switching operations used to convert an alternating current (AC) input voltage to a DC output voltage, or vice versa, or to convert a DC input voltage to a higher or lower DC output voltage. The low-profile arrangement of a flat/planar power module in particular has the effect of concentrating heat into a smaller volume, with heat radiating from one or both major surfaces of the power module depending on the internal configuration. Thermal management is often a bottleneck to efforts toward decreasing the size of a given power module while increasing its power density. Optional two-sided cooling within the confines of the disclosed manifold housing in accordance with the present teachings is thus directed toward eliminating the above-noted thermal management bottleneck and providing other benefits as described below, with one-sided cooling possible in other configurations.

The vascular jet cooling system described herein includes at least one jet impingement plate arranged in a dielectric polymer molding material. A portion of the jet impingement plate is embedded in the polymer molding material to help control the plates' relative position, e.g., using an overmolding process. Different plate configurations, possibly accompanied by incorporation of external cooling fins on the power module, may be used to enhance desirable heat transfer properties within the scope of the disclosure.

In a particular embodiment, a power module assembly is disclosed for use with an external coolant supply, with the latter proving a suitable heat transfer fluid, and with the fluid referred to hereinafter as coolant for simplicity. The power module assembly includes a planar power module having oppositely-disposed first and second major surfaces, and a manifold housing encapsulating the planar power module therewithin. The manifold housing defines a coolant inlet port configured to fluidly connect to the coolant supply and receive heat transfer fluid/coolant therefrom, an internal cavity in fluid communication with the inlet port and containing the power module, and a coolant outlet port. The coolant inlet port is in fluid communication with the internal cavity, while the coolant outlet port is configured to connect to the coolant supply and direct the coolant thereto, i.e., upon discharge of heated coolant from the manifold housing.

Within the structure of the manifold housing, a jet impingement plate is arranged in the internal cavity adjacent to a major surface. The jet impingement plate is configured to direct the coolant passing through the coolant inlet port onto the major surface. Some configurations could use two such jet impingement plates, i.e., parallel first and second jet impingement plates. In such an embodiment, the first and second jet impingement plates are arranged in the internal cavity adjacent to respective first and second major surfaces, and are configured to direct the coolant passing through the coolant inlet port onto the respective first and second major surfaces.

The jet impingement plate may be optionally configured as a nozzle plate, in which case the openings include discrete nozzles. Such nozzles, along a center axis thereof, may be cylindrical, tapered, conical, or of various other profiles as described herein.

The vascular jet cooling system may be characterized by an absence of o-rings.

Each jet impingement plate may be constructed of metal and co-molded with the dielectric polymer molding material of the manifold housing. The metal may include copper, brass, and/or aluminum in optional embodiments.

The jet impingement plate in other embodiments is constructed from the dielectric polymer molding material. The dielectric polymer molding material could include, by way of example, an epoxy-based molding compound, a silicon based-molding compound, or a phenolic based molding compound, or various other materials as set forth herein.

A power module assembly is also disclosed herein that includes the above-noted planar power module and the vascular jet cooling system. The planar power module may be constructed as a semiconductor switching device, e.g., a half-bridge inverter, in some configurations.

A method for constructing a power module assembly includes, in an exemplary embodiment, positioning the planar power module, a first jet impingement plate, and a second jet impingement plate in a first mold, with the first and second jet impingement plates defining respective sets of openings configured to direct a coolant onto a respective major surface of the power module. The method includes injecting a sacrificial material into the first mold, and removing the planar power module and the first and second jet impingement plates from the first mold after the sacrificial material hardens or solidifies.

The method in this embodiment also includes placing the planar power module, the first jet impingement plate, the second jet impingement plate, and the sacrificial material into a second mold, and thereafter injecting a dielectric polymer molding material into the second mold. The dielectric polymer molding material is then allowed to solidify or harden, thereby forming a manifold housing around the planar power module and the jet impingement plates. The method then includes removing the power module assembly from the second mold, and thereafter removing and discarding the sacrificial materials.

The above summary does not represent every embodiment or every aspect of this disclosure. Rather, the above features and advantages, and other features and attendant advantages of this disclosure, will be readily apparent from the following detailed description of illustrative examples and modes for carrying out the present disclosure when taken in connection with the accompanying drawings and the appended claims. Moreover, this disclosure expressly includes any and all combinations and sub-combinations of the elements and features presented above and below.

### BRIEF DESCRIPTION OF THE DRAWINGS

FIG. 1 is a schematic perspective view illustration of a vascular jet cooling system for a planar power module in accordance with an embodiment of the present disclosure.

FIG. 1A is a schematic partial cross-sectional exploded view illustration of the vascular jet cooling system shown in FIG. 1.

FIG. 2 is a schematic depiction of possible profiles for use in the construction of impingement plates of the vascular jet cooling system shown in FIG. 1A.

FIGS. 3 and 4 are schematic cross-sectional illustrations of the vascular jet cooling system shown in FIGS. 1 and 2 according to different embodiments.

FIG. 5 is a schematic top view illustration of a possible coolant path and nozzle configuration in accordance with a nozzle jet embodiment of the vascular jet cooling system shown in FIG. 4.

FIG. 6 is a schematic cross-sectional illustration of the vascular jet cooling system shown in FIGS. 1-5 according to an alternative slot jet embodiment.

FIG. 7 is a schematic top view illustration of a possible coolant path and nozzle configuration in accordance with the slot jet embodiment of the vascular jet cooling system shown in FIG. 6.

FIG. 8 is a flow chart describing a representative embodiment of a method of constructing the vascular jet cooling system of FIGS. 1-7.

FIG. 9 is a schematic perspective view illustration of optional cooling fins usable as part of the power module contemplated herein.

### DETAILED DESCRIPTION

The present disclosure is susceptible of embodiment in many different forms. Representative examples of the disclosure are shown in the drawings and described herein in detail as non-limiting examples of the disclosed principles. To that end, elements and limitations described in the Abstract, Introduction, Summary, and Detailed Description sections, but not explicitly set forth in the claims, should not be incorporated into the claims, singly or collectively, by implication, inference, or otherwise.

For purposes of the present description, unless specifically disclaimed, use of the singular includes the plural and vice versa, the terms “and” and “or” shall be both conjunctive and disjunctive, “any” and “all” shall both mean “any and all”, and the words “including”, “containing”, “comprising”, “having”, and the like shall mean “including without limitation”. Moreover, words of approximation such as “about”, “almost”, “substantially”, “generally”, “approximately”, etc., may be used herein in the sense of “at, near, or nearly at”, or “within 0-5% of”, or “within acceptable manufacturing tolerances”, or logical combinations thereof.

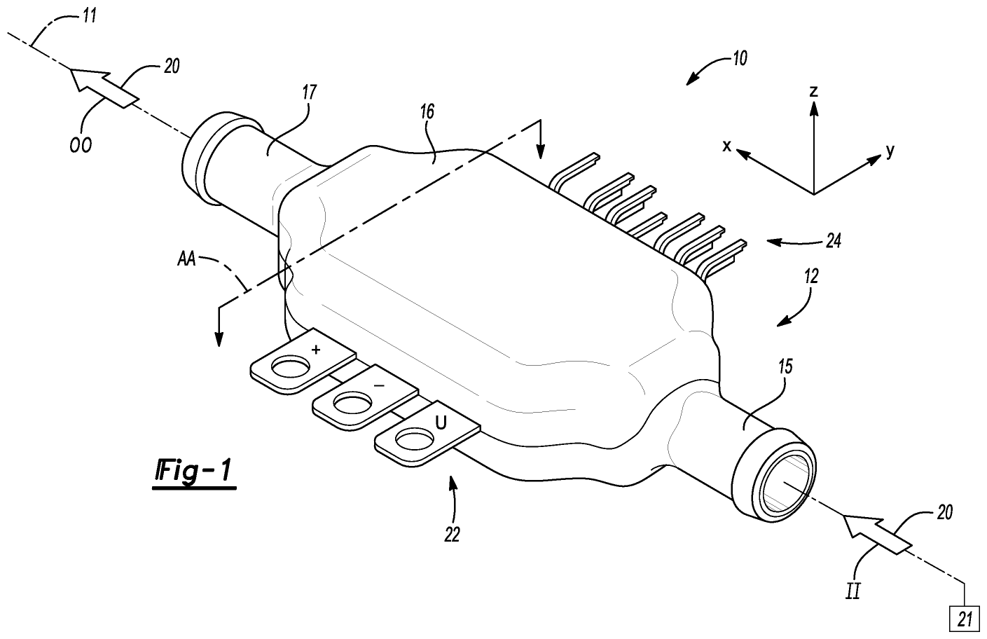

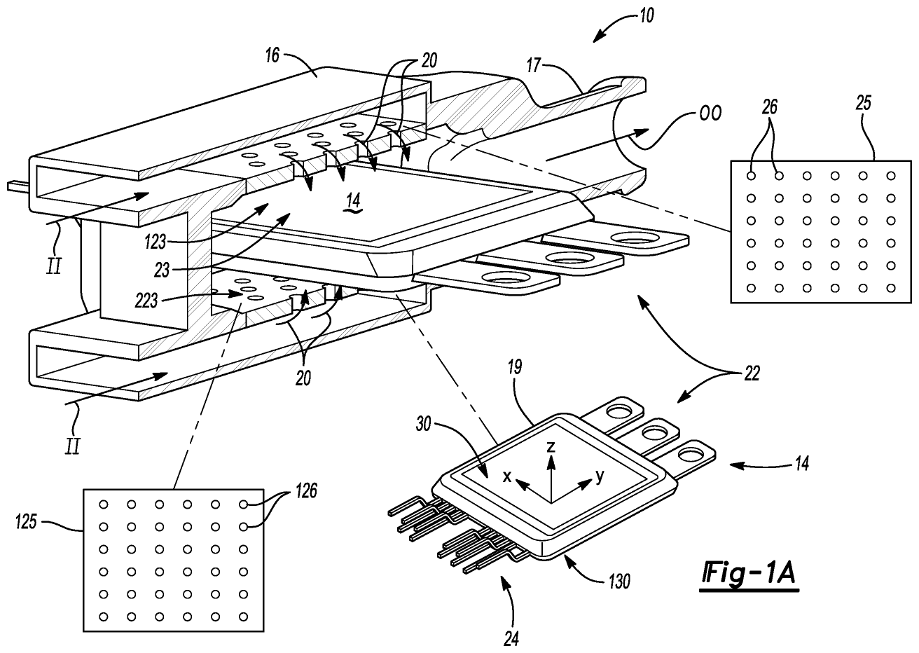

Referring to the drawings, wherein like reference numbers refer to like features throughout the several views, an exemplary embodiment of a power module assembly 10 is depicted schematically in FIGS. 1 and 1A. The power module assembly 10 as set forth herein includes a vascular jet cooling system 12 having a manifold housing 16 and a planar power module 14 encapsulated therewithin, with a representative embodiment of the power module 14 depicted in FIG. 1A. High-voltage leads 22 and low-voltage gate control pins 24 project radially outward from a manifold housing 16, i.e., in a generally orthogonal direction relative to a longitudinal axis 11 of the manifold housing 16.

In the illustrated configuration of FIGS. 1 and 1A, three such high-voltage leads 22 project radially from the planar power module 14, and are used to connect high-voltage direct current (DC) and alternating current (AC) buses (not shown) to the power module 14. Three such high-voltage leads 22 are depicted in FIGS. 1A projecting from a same or common lateral side 19 of the power module 14 for a representative single phase/half-bridge inverter or other semiconductor switching device embodiment of the power module 14, and thus the high-voltage leads 22 include a positive (+) and a negative (−) DC high-voltage lead 22, and a high-voltage AC lead 22, nominally labeled as U in FIG. 1.

While “high-voltage” as used herein means “in excess of typical 12-15V auxiliary voltage levels”, e.g., 60V or more, automotive embodiments and other mobile applications typically use voltage levels of 300-400V or more for powering propulsion functions, with such voltage levels being typical high-voltage levels within the scope of the disclosure. Those skilled in the art will appreciate that the present teachings are readily extended to other types of power modules 14, such as but not limited to multi-phase/full-bridge/6-in-1 type power inverters. For illustrative consistency, a single-phase half-bridge embodiment of the planar power module 14 will be described herein without limiting applications to such a configuration. Other semiconductor switching devices may be used in other embodiments, however, and therefore the half-bridge embodiment is non-limiting and illustrative of the present teachings.

The planar power module 14 in a representative embodiment may be configured as a power inverter module for use in a high-voltage electrical system, e.g., an electric powertrain system for a motor vehicle, a powerplant, or another stationary or mobile high-voltage system. As understood in the art and noted generally above, such a power module 14 may include multiple semiconductor switching dies in the form of bipolar transistors, insulated-gate bipolar transistors (IGBTs), metal oxide semiconductor field effect transistors (MOSFETs), thyristors, and/or diodes. Such semiconductor components, not shown but well understood in the art, are encapsulated within the module body 16 as shown in FIG. 1A and electrically connected to the high-voltage leads 22 and low-voltage gate control pins 24. In a typical electrical system, for example that of an electrified vehicle, the high-voltage leads 22 are connected to a propulsion battery pack via positive and negative bus bars, as well as to a corresponding phase winding of a rotary electric machine. Such an electric machine may be embodied as an electric propulsion motor in the example of the electrified motor vehicle. Other stationary or mobile electrical systems may benefit from the power module 14, and therefore mobile or vehicular applications are exemplary of the present teachings and non-limiting thereof

In some embodiments, the planar power module 14 of FIG. 1 may be of a composite structure, e.g., in the form of a metallized ceramic substrate, which is a ceramic substrate sandwiched between and directly bonded to layers or sheets of metal. The metallized ceramic substrate may be in the form of a direct bonded copper (DBC) or direct bonded aluminum (DBA) ceramic substrate. In either case, the ceramic substrate may be made of a ceramic material, e.g., aluminum-oxide (Al₂O₃), aluminum-nitride (AlN), and/or beryllium oxide (BeO). In DBC ceramic substrates, the ceramic substrate is sandwiched between and directly bonded to layers or sheets of copper (Cu) and/or copper oxide (CuO). In DBA ceramic substrates, the ceramic substrate is sandwiched between and directly bonded to layers or sheets of aluminum (Al).

As described in detail herein, the planar power module 14 shown in FIG. 1A is encapsulated within and co-molded with a manifold housing 16 of the vascular jet cooling system 12. An exemplary orientation of the manifold housing 16, in a representative xyz/Cartesian reference frame, is one in which the longitudinal axis 11 is arranged along the nominal x axis, i.e., lengthwise. A height dimension of the manifold housing 16 is thus arranged along the z-axis, with the y-axis describing the width.

The manifold housing 16 includes a coolant inlet port 15 and a coolant outlet port 17, with the coolant inlet port 15 and the coolant outlet port 17 being coaxially arranged along the longitudinal axis 11 in the exemplary configuration of FIG. 1. The orientation and coaxial positioning of the coolant inlet port 15 and the coolant outlet port 17 are enabled due to the high-voltage leads 22 being on the same side of the planar power module 14. Other embodiments, such as full-bridge or 6-in-1 embodiments of power module 14, may have multiple AC leads 22 projecting from an adjacent surface of the power module 14, in which case the coolant inlet port 15 and the coolant outlet port 17 may be positioned above or below the plane of the power module 14.

The coolant inlet port 15 is configured to fluidly connect to a coolant supply 21, e.g., a reservoir of an application suitable heat transfer fluid/coolant 20. As part of the disclosed operation of the vascular jet cooling system 12, the coolant 20 is directed under pressure through the manifold housing 16, such as by circulation via a coolant pump (not shown). Coolant 20 enters the manifold housing 16 through the coolant inlet port 15, with the inlet flow direction indicated in FIG. 1 by arrow II. Heat generated by high-speed switching operations within the planar power module 14 of FIG. 1A is transferred to the circulating coolant 20 as the coolant 20 impinges upon the power module 14 and passes through the manifold housing 16. The heated coolant 20 ultimately exits the manifold housing 16 via the coolant outlet port 17 as indicated in FIG. 1 by arrow OO. In this manner, the planar power module 14 is cooled by an impingement operation of the vascular jet cooling system 12.

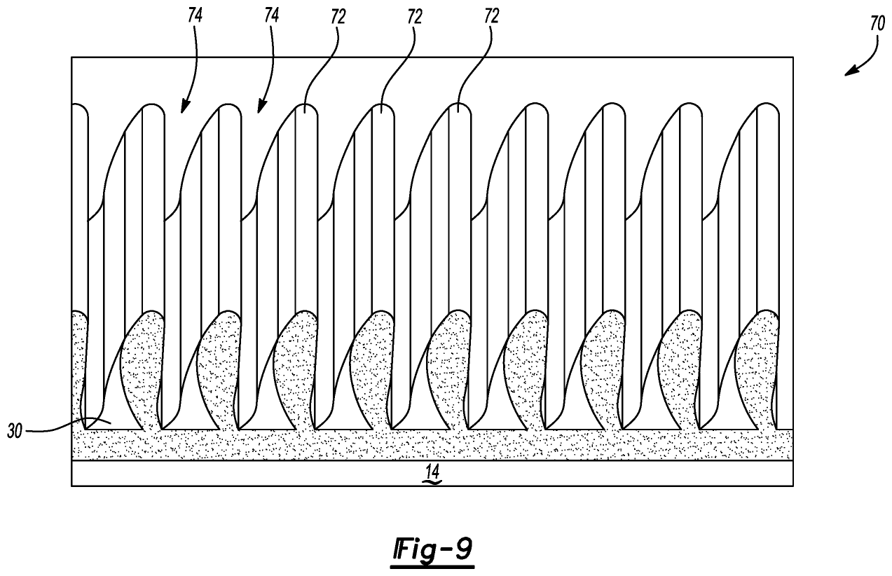

Referring briefly to FIG. 9, heat transfer efficiency enabled by the present disclosure may be enhanced by increasing the surface area of the planar power module 14. For instance, a representative first major surface 30 of the power module 14 may be equipped with surface asperities 70, exemplified in FIG. 9 as a set of cooling fins 72. The cooling fins 72 are spaced apart from each other by troughs 74, with an even spacing shown for illustrative simplicity. Other surface asperities 70 may be used within the scope of the disclosure, including evenly distributed or unevenly distributed surface roughness, variation in the height and/or width of the cooling fins 72, etc. Thus, the smooth appearance of the power module 14 in FIGS. 1 and 1A is itself exemplary and non-limiting.

The manifold housing 16 shown in FIG. 1A, which is a partial cross-sectional view of the power module assembly 10 shown in FIG. 1 taken along cut-line AA, is constructed of an electrically insulating/dielectric polymer molding material. Non-limiting exemplary materials of construction include epoxy-based molding compound, a silicon-based molding compound, or a phenolic based molding compound. The manifold housing 16 defines therein an internal cavity 23 in fluid communication with the coolant inlet port 15 of FIG. 1. The internal cavity 23, shown as a generally rectangular chamber bounded by the manifold housing 16, thus contains the power module 14. The coolant outlet port 17, which is in fluid communication with the internal cavity 23, is configured to connect to the coolant supply 21 of FIG. 1, e.g., via a network of clamps, hoses/tubing, valves, etc. In its various embodiments, the vascular jet cooling system 12 of FIGS. 1 and 1A may be characterized by an absence of o-rings, with internal sealing occurring solely via integral formation of the constituent components.

Within the scope of the present disclosure, the vascular jet cooling system 12 includes at least one jet impingement plate, i.e., one or both of a first jet impingement plate 25 and a separate second jet impingement plate 125. That is, while two-sided cooling may be used in accordance with the present teachings, e.g., when heat is radiated from the first major surface 30 and the second major surface 130, embodiments may be contemplated in which one of the first or second major surfaces 30 or 130 is cooled. Those skill in the art will appreciate that one of the jet impingement plates 25 or 125 could be eliminated in such an embodiment, with coolant 20 directed through the remaining jet impingement plate 25 or 130 to cool the respective major surface 30 or 130. Thus, single-side cooling is possible within the scope of the disclosure.

In a non-limiting two-sided cooling configuration as shown, the respective first and second jet impingement plates 25 and 125 are arranged parallel to each other within the internal cavity 23 of the manifold housing 16. The respective first and second jet impingement plates 25 and 125 are co-molded/overmolded with the manifold housing 16 as described below with particular reference to FIG. 8, and constructed of an application-suitable material. In a possible construction, the first and second jet impingement plates 25 and 125 are constructed of metal, such as but not limited to copper, brass, or aluminum. Alternatively, the respective first and second jet impingement plates 25 and 125 may be constructed from a polymer material, which may be the same dielectric polymer molding material used to construct the manifold housing 16.

The first jet impingement plate 25 of FIG. 1A defines a first set of openings 26. As explained below with reference to the remaining Figures, the first set of openings 26 directs coolant 20 passing through the coolant inlet port 15 of FIG. 1 onto a first major surface 30 of the planar power module 14. Similarly, the second jet impingement plate 125 defines a second set of openings 126, with the second set of openings 126 being configured to direct the coolant 20 passing through the coolant inlet port 15 of FIG. 1 onto a second major surface 130 of the power module 14. Heat generated from rapid switching of semiconductor switching dies (not shown) located within the power module 14 radiates to the respective first and second major surfaces 30 and 130, and is transferred to the coolant 20 impinged thereon, with the heated coolant 20 ultimately circulated out of the internal cavity 23 and through the coolant outlet port 17 as the coolant outlet flow (arrow OO).

To this end, the internal cavity 23 may be divided into upper and lower cavity chambers 123 and 223. Upon entering the manifold housing 16 through the coolant inlet port 15 of FIG. 1, under pressure from an external battery operated or engine-driven coolant pump (not shown), the coolant 20 passes into the respective upper and lower cavity chambers 123 and 223. As the upper and lower cavity chambers 123 and 223 are equally sized and equidistant from the planar power module 14 disposed within the internal cavity 23, coolant flow and heat transfer are approximately equalized across the first and second major surfaces 30 and 130.

With respect to the respective first and second jet impingement plates 25 and 125 of FIG. 1A, the sets of openings 26 and 126 collectively perform a vascular jet impingement function to radiantly cool the planar power module 14 from both sides, i.e., from its respective first and second major surfaces 30 and 130. In a possible construction, the first and second jet impingement plates 25 and 125 are embedded in the dielectric polymer molding material of the manifold housing 16, e.g., via overmolding. While the sets of openings 26 and 126 are shown as circular orifices for illustrative simplicity, those skilled in the art will appreciate that various shapes and configurations of the sets of openings 26 and 126 may be used within the scope of the disclosure to enhance heat transfer.

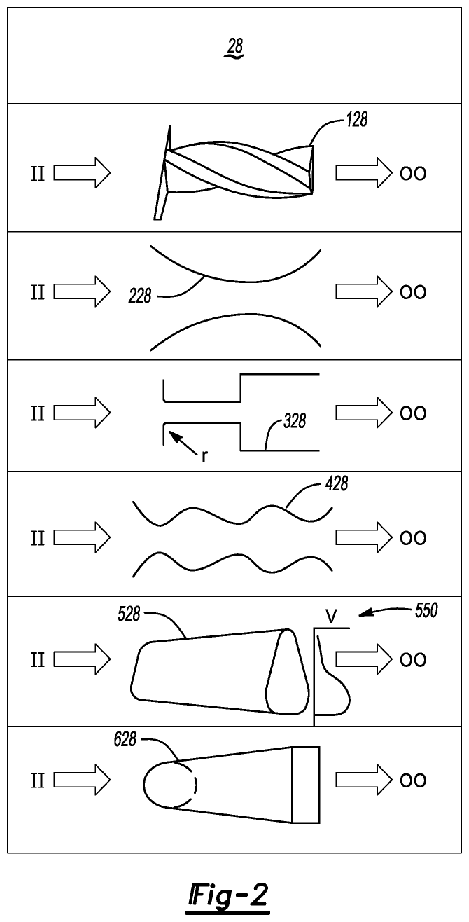

Referring briefly to FIG. 2, representative axial profiles 28 are shown for the respective first and second sets of openings 26 and 126, with the profiles 28 shown relative to the flow direction, i.e., arrows II and OO, which is along a center axis of the various openings 26 and 126. The profiles 28 may include a twisting or corkscrew-type profile 128 to impart momentum in a transverse direction, possibly enabling improved plume angle and penetration control, or a converging/diverging profile 228 to accelerate then decelerate flow of the coolant 20. Such a configuration may facilitate control of plume angle and entrainment. Other representative profiles 28 may include a defined complex profile 328 to control cavitation or flow separation, or possibly providing the sets of openings 26 and 126 with a roughness profile 428 to impart a desired degree of turbulence and promote atomization.

In still other configurations, the sets of openings 26 and 126 may have an asymmetric profile 528 to enable better mass distribution and flow control, with flow velocity (V) 550 representing such control. Alternatively, the first and second sets of openings 26 and 126 may be provided with a linear geometric transition profile 628 along their respective axes for mass distribution control and improved structural integrity. These and other profiles may be envisioned, with construction of profiles having a high level of geometric complexity enabled using additive manufacturing techniques.

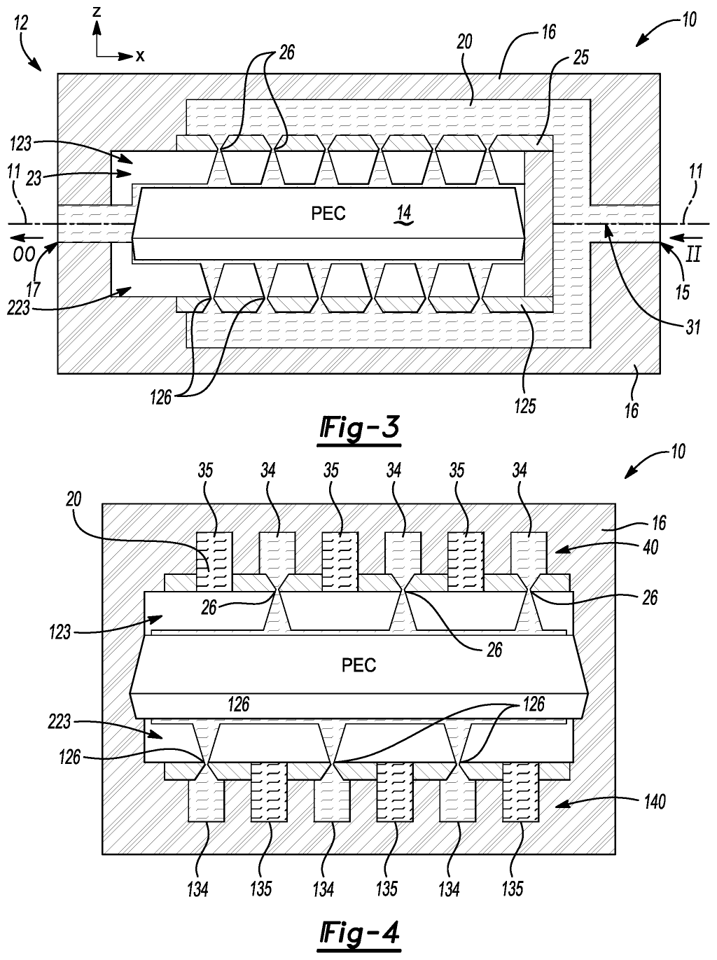

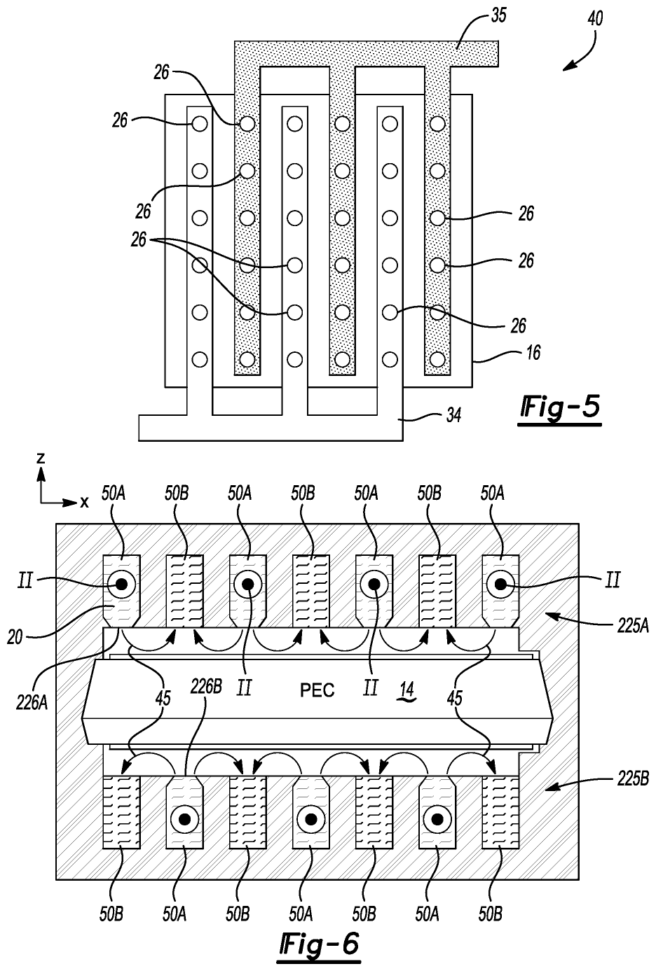

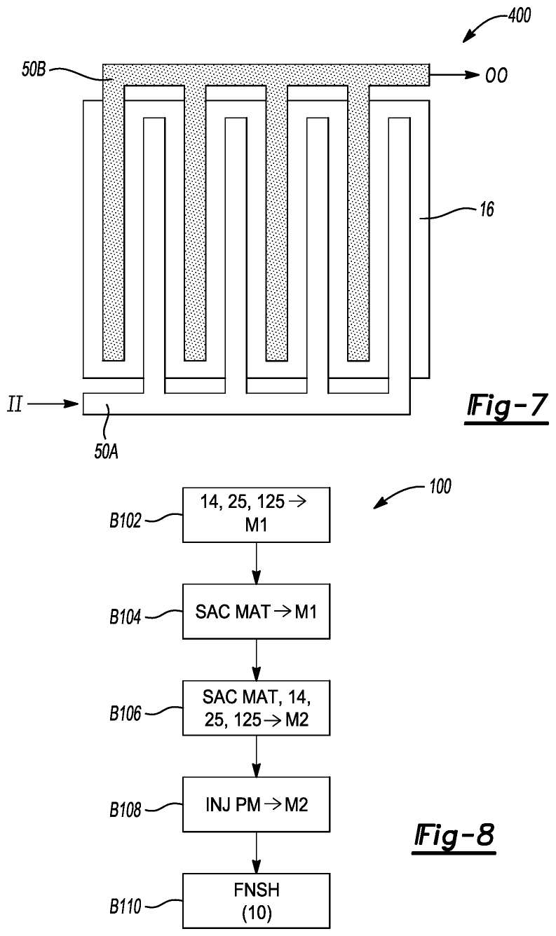

As described below, the first and second jet impingement plates 25 and 125 of FIG. 1A may be optionally configured as discrete nozzle plates, in which case the sets of openings 26 and 126 are discrete/individual nozzles having one of the profiles 28 of FIG. 2, a straight cylindrical profile, or another suitable profile 28. Example nozzle plate-configurations for the first and second jet impingement plates 25 and 125 are depicted in FIGS. 3-5 and described in detail below. Alternatively, the first and second jet impingement plates 25 and 125 may be configured as slot plates as shown in FIGS. 6 and 7, in which case the respective first and second sets of openings 26 and 126 are constructed as elongated, continuous slots.

Referring to FIG. 3, the power module assembly 10 is depicted in a schematic cross-sectional view along the indicated xz axes of the above-noted xyz reference frame. Inlet flow (arrow II) of the coolant 20 enters the manifold housing 16 via the coolant inlet port 15, external structure of which is omitted for clarity but depicted in FIG. 1. The coolant 20 divides at a terminal end 31 of the coolant inlet port 15 before passing through the first and second sets of openings 26 and 126 onto the planar power module 14, abbreviated “PEC” for “power electronic component”, e.g., a half-bridge or full-bridge power inverter module. Heated coolant 20 then exits the manifold housing 16 via the coolant outlet port 17 as outlet flow (arrow OO). A downstream heat exchanger (not shown) could be used to extract the heat and return the coolant 20 to the coolant supply 21 of FIG. 1 for recirculation to the coolant inlet port 15, as will be appreciated by those skilled in the art.

An alternative configuration to the embodiment of FIGS. 1-3 is shown in FIGS. 4 and 5. Here, the first set of openings 26 is serviced by inlet fluid channels 34, 134 that are connected to or integrally formed with a respective coolant manifold 40 and 140, with a representative configuration of the coolant manifold 40 depicted schematically in FIG. 5. Coolant manifold 140, shown in FIG. 5, is representative of the coolant manifold 140, and therefore is illustrative of the relevant structural features thereof. A similar network of outlet channels 35 and 135 is created for recovering the coolant 20. While the perspective of FIG. 4 illustrates the first set of openings 26 used to direct coolant 20 onto the planar power module 14, similar openings 26 are shown in FIG. 5 for the purpose of extracting the heated coolant 20.

Recovery of heated coolant 20 in the embodiment of FIGS. 4 and 5 may be aided by suction or purposeful orientation that favors the heated coolant 20 being directed in the desired manner. Also, while the internal cavity 23 is shown with air pockets to better illustrate injection of a conical jet of coolant 20 and subsequent impingement upon the power module 14, the internal cavity 23 may be completely filled with coolant 20 in an actual embodiment, depending on the size of the internal cavity 23 and the injection rate of the coolant 20.

Yet another embodiment of the power module assembly 10 is shown in FIGS. 6 and 7. Here, the nozzle jet configuration of FIGS. 2-5 is replaced with a slot plate embodiment of the first and second jet impingement plates 25 and 125 described above, i.e., as slot plates 225A and 225B. In the depicted embodiment, coolant 20 enters from a coolant manifold 400, as indicted at II in FIG. 6. A representative configuration of the coolant manifold 400 is depicted in a schematic plan view illustration in FIG. 7. The admitted coolant 20 (arrow II) is conducted along the full lengths of the coolant inlet slots 50A, each being elongated continuous openings as opposed to discrete opening as in the earlier described embodiments, and onto the exposed first major surface 30 of the planar power module 14. A similar coolant manifold 400 would be positioned to perform the same function for the exposed second major surface 130 of FIG. 6. Heated coolant 20 then passes into the adjacent coolant outlet slots 50B, where the heated coolant 20 ultimately passes out of the manifold housing 16 as outlet flow (arrow OO).

The coolant inlet slots 50A of FIG. 7 are interspaced with coolant outlet slots 50B, such that a given coolant inlet slot 50A is immediately adjacent to a neighboring coolant outlet slot 50B. As shown in FIG. 6, terminal ends of the coolant inlet slots 50A are thus configured as slot jets 226A and 226B, with arrows 45 representing the flow of coolant 20 between coolant inlet slots 50A and adjacent coolant outlet slots 50B. Each coolant slot 50A and 50B has a generally constant cross-section as shown in FIG. 6, with the particular profile of the slot jets 226A and 226B increased via a tapered reduction in flow area as shown. As depicted, the coolant slots 50A and 50B are constructed from the same dielectric polymer molding material used to construct the manifold housing 16. In other embodiments, however the coolant slots 50A and 50B could be constructed of metal or other suitable materials.

Referring now to FIG. 8, a method 100 for fabricating the power module assembly 10 shown in the representative embodiment of FIGS. 1-3 commences, in a representative embodiment, with block B102. Block B102 includes positioning the planar power module 14, the first jet impingement plate 25, and the second jet impingement plate 125 in a first mold. As explained above, the respective first and second jet impingement plates 25 and 125 define the sets of openings 26 and 126, which in turn are configured to direct the coolant 20 onto a respective first or second major surface 30 or 130 of the power module 14. The sequence of block B102 is abbreviated in FIG. 8 as 14, 25, 125→M1, with M1 representing the above-noted first mold. As understood in the art, such a mold is configured to support and retain the power module 14 and the first and second jet impingement plates 25 and 125 in a desired relative position prior to a subsequent overmolding or co-molding step. The method 100 proceeds to block B104 once the components have been placed in this manner.

Block B104 includes injecting a sacrificial material into the first mold. The injected sacrificial material is then allowed to solidify or harden, with this sequence abbreviated SAC MAT→M1 in FIG. 8. The method 100 then proceeds to block B106.

With respect to the sacrificial material used in block B104, such a material or combination thereof may be introduced using compression molding, vacuum forming, thermoforming, injection molding, blow molding, profile extrusion, or a combination thereof. The sacrificial material may be introduced in the form of a liquid or relatively soft material, and may be allowed to solidify or harden within the first mold, e.g., by cooling and/or by curing. The sacrificial material contemplated herein is “sacrificial” in the sense of being removable from the first mold without harming the physical and/or structural integrity of the power module 14 and the first and second jet impingement plates 25 and 125 shown in FIG. 1A.

In some embodiments, the sacrificial material used as part of block B104 may be a material that exhibits a solid phase at ambient temperature, but upon heating to a temperature less than about 175° C., transitions to a liquid phase or a gas phase. The sacrificial material may be a material that exhibits a solid phase at ambient temperature, but thermally decomposes (e.g., pyrolyzes or oxidizes) upon heating to a temperature greater than ambient temperature but less than 175° C. The sacrificial material may be soluble in an aqueous medium (e.g., water) or a nonaqueous medium (e.g., acetone), or dissolved by a chemical etchant such as an acid, e.g., hydrochloric acid, sulfuric acid, and/or nitric acid.

Embodiments of the sacrificial material include a metal alloy solder having a melting point less than 175° C., e.g., a tin-based alloy solder. Combustible materials usable in some embodiments of the sacrificial material in block B104 include black powder, i.e., a mixture of sulfur, charcoal, and potassium nitrate, pentaerythritol tetranitrate, a combustible metal, a combustible oxide, a thermite, nitrocellulose, pyrocellulose, a flash powder, and/or a smokeless powder. Such combustible materials may have flash points of less than 175° C. Examples of water-soluble materials that may be used for the sacrificial material include inorganic salts and/or metal oxides, e.g., sodium chloride, potassium chloride, potassium carbonate, sodium carbonate, calcium chloride, magnesium chloride, sodium sulphate, magnesium sulfate, and/or calcium oxide. Examples of polymeric materials that may be formulated to thermally decompose at temperatures less than 175° C. and thus may be used for the sacrificial material include polylactic acid (PLA), polyethylene terephthalate (PET), biaxially oriented polyethylene terephthalate (BOPET), cellulose, polypropylene, high density or low density polyethylene (HDPE, LDPE), acrylonitrile butadiene styrene (ABS), poly(alkylene carbonate) copolymers, and combinations thereof

Block B106, which is arrived at from block B104 upon the solidifying or hardening of the sacrificial material at block B104, entails removing the planar power module 14, the first jet impingement plate 25, the second jet impingement plate 125, with the above-described sacrificial materials still in place. The removed components are thereafter placed into a second mold, a process sequence that is abbreviated “SAC MAT, 14, 25, 125→M2”. The method 100 proceeds to block B108 once this sequence is complete.

Block B108 entails injecting a dielectric polymer molding material into the second mold to thereby form the manifold housing 16 of FIGS. 1 and 1A, with this sequence abbreviated “INJ PM→M2” in FIG. 8. The materials are then allowed to solidify and harden within the second mold, thereby forming the manifold housing 16 around the planar power module 14, the first jet impingement plate 25, and the second jet impingement plate 125. The method 100 proceeds to block B110 once hardening is complete.

With respect to the manifold housing 16 shown in FIG. 1A, suitable materials of construction may include a thermosetting or a thermoplastic polymeric material in different embodiments. The particular polymer material used for constructing the manifold housing 16 could be introduced into a mold as a liquid or a relatively soft malleable material and allowed to solidify therein by cooling and/or curing. Representative materials of construction of the manifold housing 16 include, but are not limited to, epoxy, silicon, or phenolic as noted above, as well as polyurethane, polyimide, polypropylene, nylon, thermoplastic olefin, polycarbonate, polytetrafluoroethylene, and/or combinations thereof

The manifold housing 16 described above may be of a unitary one-piece construction, i.e., formed around the planar power module 14 and the first and second jet impingement plates 25 and 125 in a single manufacturing step. In other embodiments, the manifold housing 16 may be formed as two discrete, symmetrical halves, positioned around the power module 14, and thereafter bonded to one another using an application-suitable adhesive or sealant, or via ultrasonic welding or weld bonding techniques. The adhesive or sealant used to bond the manifold housing 16 may be constructed of an elastomeric polymeric material cured at room temperature. Such an adhesive/sealant may be a silicon-based polymeric material, e.g., a room-temperature -vulcanizing (RTV) silicone in some embodiments.

At block B110, the method 100 next includes removing the power module assembly 10 of FIG. 1 from the second mold, and then removing the sacrificial materials. The end result of block B110 is the provision of the power module assembly 10. Removal of the sacrificial materials depends on the particular materials used, with various types described above. Such materials may be water soluble or dissolvable in a particular solvent, for instance, or combustible, frangible, or removable in a host of ways depending on the particular construction, with removal in such embodiments including flushing with the noted water or solvent, application of vibration energy, combustion, etc. Additional machining or finishing techniques may be applied as part of block B110 to finish the power module assembly 10 as needed, with this sequence abbreviated FNSH (10) in FIG. 7.

The present teachings enable construction of a planar power module 14 that can be cooled from both sides by an array of impinging jets, with various examples shown in FIGS. 1A-7. The manifold housing 16 shown in the various Figures may support metal or co-molded polymer embodiments of the respective first and second jet impingement plates 25 and 125 of FIG. 1A, with the manifold housing 16 self-sealing against the power module 14, i.e., the heat source, to thereby retain coolant 20 within the internal cavity 23. Self-sealing may be achieved using mechanical pressure, chemical adhesion, or both. Coupled with the various geometries of FIG. 2 and the alternating channel configurations of FIGS. 3-7 and the optional external cooling fins 72 of FIG. 9, therefore, one may enable two-sided cooling of the power module 14 of FIG. 1A. These and other benefits will be readily appreciated by those skilled in the art in view of the foregoing disclosure.

The detailed description and the drawings or figures are supportive and descriptive of the present teachings, but the scope of the present teachings is defined solely by the claims. While some of the best modes and other embodiments for carrying out the present teachings have been described in detail, various alternative designs and embodiments exist for practicing the present teachings defined in the appended claims. Moreover, this disclosure expressly includes combinations and sub-combinations of the elements and features presented above and below.

What is claimed is:

1. A vascular jet cooling system for use with a planar power module and a coolant supply, the vascular jet cooling system comprising:
a manifold housing constructed of a dielectric polymer molding material, and defining at least one coolant inlet port configured to fluidly connect to the coolant supply to receive a coolant therefrom, an internal cavity in fluid communication with the coolant inlet port and configured to contain the planar power module therein, and a coolant outlet port in fluid communication with the internal cavity, the coolant outlet port being configured to connect to the coolant supply; and
a jet impingement plate defining openings and arranged in the internal cavity, the openings being configured to direct the coolant passing through the coolant inlet port onto a major surface of the planar power module.

2. The vascular jet cooling system of claim 1, wherein the jet impingement plate includes a first jet impingement plate defining a first set of the openings and arranged in the internal cavity, the first set of the openings being configured to direct the coolant passing through the coolant inlet port onto a first major surface of the planar power module; and
a second jet impingement plate defining a second set of the openings and arranged in the internal cavity, the second set of the openings being configured to direct the coolant passing through the coolant inlet port onto a second major surface of the planar power module.

3. The vascular jet cooling system of claim 1, wherein the jet impingement plate is configured as a nozzle plate, and wherein the openings include discrete nozzles.

4. The vascular jet cooling system of claim 1, wherein the jet impingement plate is configured as a slot jet plate, and wherein the openings are elongated slots.

5. The vascular jet cooling system of claim 1, wherein the vascular jet cooling system is characterized by an absence of o-rings.

6. The vascular jet cooling system of claim 1, wherein the jet impingement plate is constructed of metal, and is co-molded or overmolded with the dielectric polymer molding material of the manifold housing.

7. The vascular jet cooling system of claim 1, wherein the jet impingement plate is constructed from the dielectric polymer molding material.

8. The vascular jet cooling system of claim 1, wherein the dielectric polymer molding material includes an epoxy-based molding compound, a silicon based-molding compound, or a phenolic based molding compound.

9. A power module assembly comprising:
a planar power module; and
a vascular jet cooling system, including:
a polymer manifold housing constructed of a dielectric polymer molding material and defining a coolant inlet port, the coolant inlet port being configured to fluidly connect to a coolant supply to receive a coolant, an internal cavity in fluid communication with the coolant inlet port and containing the planar power module therein, and a coolant outlet port in fluid communication with the internal cavity, the coolant outlet port being configured to connect to the coolant supply;
a first jet impingement plate defining a first set of openings and arranged in the internal cavity, the first set of openings being configured to direct the coolant passing through the coolant inlet port onto a first major surface of the planar power module; and
a second jet impingement plate defining a second set of openings and arranged in the internal cavity, the second set of openings being configured to direct the coolant passing through the coolant inlet port onto a second major surface of the planar power module.

10. The power module assembly of claim 9, wherein the first jet impingement plate and the second jet impingement plate are configured as nozzle plates, and wherein the first set of openings and the second set of openings are respective sets of discrete nozzles.

11. The power module assembly of claim 9, wherein the first jet impingement plate and the second jet impingement plate are configured as slot jet plates, and wherein the first set of openings and the second set of openings are respective sets of elongated slots.

12. The power module assembly of claim 9, wherein the vascular jet cooling system is characterized by an absence of o-rings.

13. The power module assembly of claim 9, wherein the first jet impingement plate and the second impingement plate are constructed of metal that is co-molded with the dielectric polymer molding material of the manifold housing.

14. The power module assembly of claim 9, wherein the first jet impingement plate and the second jet impingement plate are constructed from the dielectric polymer molding material.

15. The power module assembly of claim 14, wherein the dielectric polymer molding material includes an epoxy-based molding compound or silicone-based molding compound.

16. The power module assembly of claim 9, wherein the first major surface of the planar power module and/or the second major surface of the planar power module includes cooling fins configured to radiate heat away from the planar power module.

17. The power module assembly of claim 9, wherein the planar power module is a semiconductor switching device.

18. A method for constructing a power module assembly, the method comprising:
positioning a planar power module, a first jet impingement plate, and a second jet impingement plate in a first mold, wherein the first jet impingement plate and the second jet impingement plate defines respective sets of openings configured to direct a coolant onto a respective major surface of the planar power module;
injecting a sacrificial material into the first mold;
removing the planar power module, the first jet impingement plate, and the second jet impingement plate from the first mold after the sacrificial material hardens or solidifies;
placing the planar power module, the first jet impingement plate, the second jet impingement plate, and the sacrificial material into a second mold;
injecting a dielectric polymer molding material into the second mold;
allowing the dielectric polymer molding material to solidify or harden, thereby forming a manifold housing around the planar power module, the first jet impingement plate, and the second jet impingement plate;
removing the power module assembly from the second mold; and
removing the sacrificial material to thereby provide the power module assembly.

19. The method of claim 18, wherein the first jet impingement plate and the second jet impingement plate are configured as nozzle plates or slot jet plates, and wherein the respective sets of openings are sets of discrete nozzles or sets of elongated slots, respectively.

20. The method of claim 18, wherein the first jet impingement plate and the second jet impingement plate are constructed of metal.
